(19) United States
(12) Patent Application Publication
(10) Pub. No.: US 2023/0217788 A1
(43) Pub. Date: Jul. 6, 2023

(54) DISPLAY DEVICE AND ELECTRONIC DEVICE

(71) Applicant: SAMSUNG DISPLAY CO., LTD., Yongin-si (KR)

(72) Inventors: Kangyoon Kim, Yongin-si (KR); Dongcheon Shin, Yongin-si (KR); Tecksoo Kim, Yongin-si (KR)

(21) Appl. No.: 18/147,404

(22) Filed: Dec. 28, 2022

(30) Foreign Application Priority Data
Dec. 30, 2021 (KR) 10-2021-0193431

(51) Int. Cl. H10K 59/80; H10K 59/60

(52) U.S. Cl. CPC H10K 59/873; H10K 59/60

(57) ABSTRACT

Provided are a display device and an electronic device including the same, the display device including: a display element arranged in a display area of a display substrate, and including a first electrode, a second electrode, and an emission layer arranged therebetween; an encapsulation member disposed on the display element; and a window disposed on the encapsulation member, in which the window includes: a window substrate including a transmission area and a bezel area located outside the transmission area; a first printed layer disposed on the window substrate in the bezel area, and including a first pigment particle distributed in a first base material; and a second printed layer disposed on the first printed layer in the bezel area, and including an opening overlapping the first printed layer, in which a size of the first pigment particle is about 0.5 μm to about 5 μm in diameter.

### CROSS-REFERENCE TO RELATED APPLICATION

This application claims priority under 35 U.S.C. § 119 to Korean Patent Application No. 10-2021-0193431, filed on Dec. 30, 2021, in the Korean Intellectual Property Office, the disclosure of which is incorporated by reference herein in its entirety.

### TECHNICAL FIELD

Embodiments of the present disclosure relate to a display device and an electronic device.

### DISCUSSION OF RELATED ART

Various types of electronic devices based on mobile technology are being used, and such an electronic device, for example, a smartphone, a tablet or other mobile device, may include a display panel providing an image and a window protecting the display panel.

In general, the window includes, at a center, a transmission area corresponding to a display area of the display panel for displaying the image, at an edge, a bezel area where a user is unable to recognize the image, and internal wires or components of the electronic device are located in the bezel area. Accordingly, a printed layer may be formed in the bezel area such that the wires, components, and the like are not easily seen from the outside, thereby enhancing aesthetic of the electronic device. Also, the printed layer of the bezel area may have an area corresponding to a component arranged therebelow and being designed to have optical characteristics required by the component, for example, a sensor.

### SUMMARY

Embodiments of the present disclosure include an electronic device including a window to which a sensor, such as a proximity sensor and/or an illumination sensor, is applicable. However, the presented embodiments are only examples and the scope of the present disclosure is not limited thereto.

Additional aspects will be set forth in part in the description which follows and, in part, will be apparent from the description, or may be learned by practice of the presented embodiments of the present disclosure.

According to an embodiment of the present disclosure, a display device includes a display substrate, a display element arranged in a display area of the display substrate, and including a first electrode, a second electrode, and an emission layer arranged between the first electrode and the second electrode, an encapsulation member disposed on the display element, and a window disposed on the encapsulation member, in which the window includes a window substrate including a transmission area and a bezel area located outside the transmission area, a first printed layer disposed on the window substrate in the bezel area, and including a first pigment particle distributed in a first base material, and a second printed layer disposed on the first printed layer in the bezel area, and including an opening overlapping the first printed layer, in which a size of the first pigment particle is about 0.5 μm to about 5 μm in diameter.

The first pigment particle may include carbon black.

The second printed layer may include a second pigment particle.

The second pigment particle may include a material the same as that of the first pigment particle.

The second pigment particle may include carbon black.

A size of the second pigment particle may be greater than the size of the first pigment particle.

The second printed layer may have a step difference from the first printed layer.

The second printed layer may have a light transmittance in a visible light area lower than that of the first printed layer.

A light transmittance of the first printed layer in an infrared area may be equal to or greater than about 80%.

According to an embodiment of the present disclosure, an electronic device includes a display device including a display element arranged in a display area of a display substrate, and a window disposed on the display element, and a housing accommodating the display device, in which the window includes a window substrate including a transmission area and a bezel area outside the transmission area, a first printed layer disposed on the window substrate in the bezel area, and including a first pigment particle distributed in a first base material, and a second printed layer disposed on the first printed layer in the bezel area, and including an opening overlapping the first printed layer, in which a size of the first pigment particle is about 0.5 μm to about 5 μm in diameter.

The electronic device may further include a sensor overlapping the opening of the second printed layer.

The sensor may include a proximity sensor and/or an illumination sensor.

The first pigment particle may include carbon black.

The second printed layer may include a second pigment particle.

The second pigment particle may include a material the same as that of the first pigment particle.

The second pigment particle may include carbon black.

A size of the second pigment particle may be greater than the size of the first pigment particle.

The second printed layer may have a step difference from the first printed layer.

The second printed layer may have a light transmittance in a visible light area lower than that of the first printed layer.

A light transmittance of the first printed layer in an infrared area may be equal to or greater than about 80%.

According to an embodiment of the present disclosure, a display device includes a display substrate, a display element arranged in a display area of the display substrate, and including a first electrode, a second electrode, and an emission layer arranged between the first electrode and the second electrode, an encapsulation member disposed on the display element, and a window disposed on the encapsulation member, in which the window includes a window substrate including a transmission area and a bezel area located outside the transmission area, a first printed layer disposed on the window substrate in the bezel area, and including a first pigment particle distributed in a first base material, and a second printed layer including a second pigment particle, disposed on the first printed layer in the bezel area, and including an opening overlapping the first printed layer, in which a size of the second pigment particle is greater than a size of the first pigment particle.

### BRIEF DESCRIPTION OF THE DRAWINGS

The above and other aspects and features of embodiments of the present disclosure will be more apparent from the following description taken in conjunction with the accompanying drawings, in which:

FIG. 1 is a perspective view schematically showing an electronic device according to an embodiment of the present disclosure;

FIG. 2 is an exploded perspective view schematically showing an electronic device according to an embodiment of the present disclosure;

FIG. 3 is a cross-sectional view of the electronic device taken along line I-I′ of FIG. 1, according to an embodiment of the present disclosure;

FIG. 4 is a cross-sectional view of a display device that may be included in the electronic device, taken along line V-V′ of FIG. 1, according to an embodiment of the present disclosure;

FIG. 5 is a cross-sectional view of the electronic device taken along line II-II′ of FIG. 1, according to an embodiment of the present disclosure;

FIGS. 6 and 7 are each a cross-sectional view of a window that may be included in the electronic device, taken along line III-III′ of FIG. 2, according to an embodiment of the present disclosure; and

FIG. 8 is a cross-sectional view of a window that may be included in the electronic device, taken along line IV-IV′ of FIG. 2, according to an embodiment of the present disclosure.

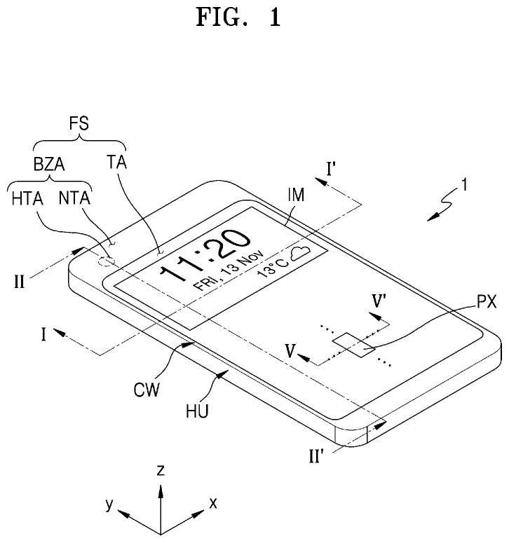

Since the drawings in FIGS. 1-8 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Reference will now be made in detail to embodiments of the present disclosure, examples of which are illustrated in the accompanying drawings, in which like reference numerals refer to like elements throughout. In this regard, the embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The present disclosure may have various modifications and various embodiments, and specific embodiments are illustrated in the drawings and described in detail in the written description. Effects and features of the present disclosure and methods of achieving the same will become apparent by referring to embodiments described in detail with reference to the accompanying drawings. However, the present disclosure is not limited to the embodiments described below, and may be implemented in various forms.

In the following embodiments, the terms “first” and “second” are not used in a limited sense and are used to distinguish one component from another component.

In the following embodiments, an expression used in the singular encompasses the expression of the plural, unless it has a clearly different meaning in the context.

It will be further understood that the terms “comprise” and/or “comprising” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

In the specification, “A and/or B” denotes only A, only B, or both A and B. Also, in the present specification, “at least one of A and B” denotes only A, only B, or both A and B.

In the following embodiments, when a wire “extends in a first direction or a second direction”, the wire may not only extend linearly, but also extend in zigzags or in a curve along the first direction or the second direction.

In the following embodiments, “on a plane” denotes that a target portion is viewed from above and “on a cross section” means that a vertically cut cross section of a target portion is viewed from side. In the following embodiments, “overlapping” denotes overlapping “on a plane” and “on a cross section”.

Hereinafter, embodiments will be described in detail with reference to the accompanying drawings, and in the following description with reference to the drawings, like reference numerals refer to like elements.

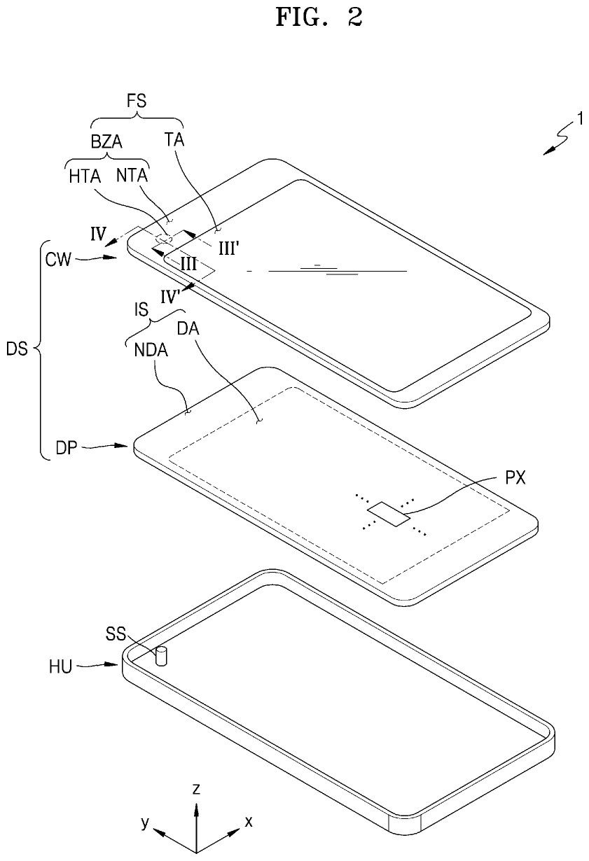

FIG. 1 is a perspective view schematically showing an electronic device 1 according to an embodiment of the present disclosure, and FIG. 2 is an exploded perspective view schematically showing the electronic device 1 according to an embodiment of the present disclosure.

Referring to FIGS. 1 and 2, the electronic device 1 is a device configured to display a moving image or a still image, and may be used not only as a display screen of portable electronic devices, such as, for example, a mobile phone, a smart phone, a tablet personal computer, a mobile communication terminal, an electronic notebook, an electronic book, a portable multimedia player (PMP), a navigation device, and an ultra mobile personal computer (UMPC), but also as a display screen of various products, such as, for example, a television, a laptop computer, a monitor, a billboard, and Internet of things (IoT). Also, the electronic device 1 according to an embodiment of the present disclosure may be used for wearable devices, such as, for example, a smart watch, a watch phone, a glasses-type display, and a head mounted display (HMD). In addition, the electronic device 1 according to an embodiment of the present disclosure may be used as a display in an instrument panel of a vehicle, a center information display (CID) arranged on a center fascia or dashboard of a vehicle, a room mirror display replacing a side mirror of a vehicle, or a display arranged on a rear surface of a front seat for providing entertainment content to a passenger in a back seat of a vehicle. In FIG. 1, for convenience of description, the electronic device 1 according to an embodiment of the present disclosure is used as a smart phone.

The electronic device 1 may have a rectangular shape on a plane. For example, the electronic device 1 may have a rectangular planar shape having a short side in an x-direction and a long side in a y-direction, as shown in FIG. 1. A corner where the short side in the x-direction and the long side in the y-direction meet may be formed to have a round shape with a predetermined curvature or have a right-angled shape. The electronic device 1 is not limited to have a rectangular planar shape, and may have, for example, a circular shape, an oval shape, an atypical shape, or another polygonal shape such as, for example, a triangle, a pentagon or a hexagon.

While the electronic device 1 having a flat shape is illustrated in FIG. 1, the electronic device 1 according to an embodiment of the present disclosure may include a 3D-type display surface or a curved display surface. When the electronic device 1 includes a 3D-type display surface, the electronic device 1 may include a plurality of display areas oriented in different directions from each other, for example, a polygonal pillar-type display surface. For example, images of the 3D-type display surface may be generated within a display volume rather than upon a stationary surface, and may include a polyprism surface. According to an embodiment of the present disclosure, when the electronic device 1 includes a curved display surface, the electronic device 1 may include a flexible material, and may be bendable, foldable, and/or rollable.

The electronic device 1 may display an image IM towards a z-direction, on a display surface FS parallel in each of the x-direction and the y-direction. The display surface FS where the image IM is displayed may correspond to a front surface of the electronic device 1, and correspond to a front surface of a window CW. Hereinafter, the display surface FS of the electronic device 1, the front surface of the electronic device 1, and the front surface of the window CW use a same reference sign, i.e., FS. The image IM includes not only a moving image, but also a still image.

In the current embodiment, front surfaces (or top surfaces) and rear surfaces (or bottom surfaces) of members are defined based on a direction in which the image IM is displayed. The front surface and the rear surface face each other in the z-direction, and normal directions of the front surface and the rear surface may be parallel to the z-direction.

The electronic device 1 may include a display device DS and a housing HU. The housing HU may have at least one opened surface, and the opened surface of the housing HU may be covered by the display device DS. The display device DS may include the window CW and a display panel DP disposed on a rear surface of the window CW. A cover protecting the display panel DP may be further included in a rear surface of the display panel DP.

The housing HU may accommodate the display panel DP. In FIG. 2, the housing HU integrally surrounds edges of the display panel DP, but the present disclosure is not limited thereto. According to an embodiment of the present disclosure, the housing HU may not be an integrated type, but may have a form in which two or more members are combined. In addition to the display panel DP, components required to drive the electronic device 1, for example, a power supply unit, such as, for example, a battery, a circuit board, or the like, may be mounted inside the housing HU. Also, according to an embodiment of the present disclosure, a sensor SS, such as a proximity sensor and/or an illumination sensor, may be mounted inside the housing HU. According to an embodiment of the present disclosure, the window CW and the housing HU may be combined to configure an exterior of the electronic device 1. For example, the display panel DP may be enclosed by the window CW and the housing HU. In other words, the window CW may couple with the housing HU to fix in place the display panel DP. In an embodiment of the present disclosure, the housing HU may include a plurality of frames and/or plates made of, for example, glass, plastic, metal, or a combination thereof.

Referring to FIGS. 1 and 2, the front surface FS of the window CW may define the front surface of the electronic device 1, and may include a transmission area TA and a bezel area BZA. The electronic device 1 displays the image IM in the transmission area TA. The transmission area TA may be an optically transparent area. For example, the transmission area TA may exhibit a light transmittance of about 90% or greater in a visible light area. When the term “about” is used in this specification in connection with a numerical value, it is intended that the associated numerical value includes a tolerance of up to ±10% around the stated numerical value.

The bezel area BZA may define a shape of the transmission area TA. The bezel area BZA may be adjacent to the transmission area TA and surround the transmission area TA. For example, the bezel area BZA may be located outside the transmission area TA. However, the present disclosure is not limited thereto, and the bezel area BZA may be disposed adjacent to only one side of the transmission area TA. The bezel area BZA may be an area having a relatively low light transmittance compared to the transmission area TA, and may include an opaque material that blocks a light. The bezel area BZA may have a certain color. According to an embodiment of the present disclosure, the bezel area BZA may be defined by a printed layer formed on a transparent substrate. The bezel area BZA may include a non-transmission area NTA and a semi-transmission area HTA. The non-transmission area NTA may be defined as an area surrounding the semi-transmission area HTA. The semi-transmission area HTA may be an area having an optical characteristic required by the sensor SS. According to an embodiment of the present disclosure, the semi-transmission area HTA may overlap the sensor SS, such as, for example, a proximity sensor and/or an illumination sensor.

The display panel DP may include a display area DA and a non-display area NDA outside the display area DA. The non-display area NDA may at least partially overlap the bezel area BZA of the window CW. The non-display area NDA may be an area covered by the bezel area BZA, and may be an area where the image IM is not displayed. For example, the bezel area BZA may cover the non-display area NDA of the electronic device 1 so as to prevent the non-display area NDA from being visually recognized from the outside. A driving circuit, a driving wire, or the like for driving the display area DA may be arranged in the non-display area NDA.

The display panel DP may provide the image IM via an array of a plurality of sub-pixels PX arranged in the display area DA. In an embodiment of the present disclosure, the sub-pixels PX may be arranged in various forms such as, for example, a stripe arrangement, a pentile arrangement, a mosaic arrangement, and the like, to implement the image IM. The image IM generated by the display panel DP may be visible to a user from the outside by being displayed on a display surface IS of the display panel DP through the transmission area TA of the window CW. Each of the sub-pixels PX may include a display element (or a light-emitting element) electrically connected to a sub-pixel circuit. The display element may include a light-emitting diode, for example, an organic light-emitting diode including an organic emission layer. The plurality of sub-pixels PX may each emit, for example, red, green, blue, or white light.

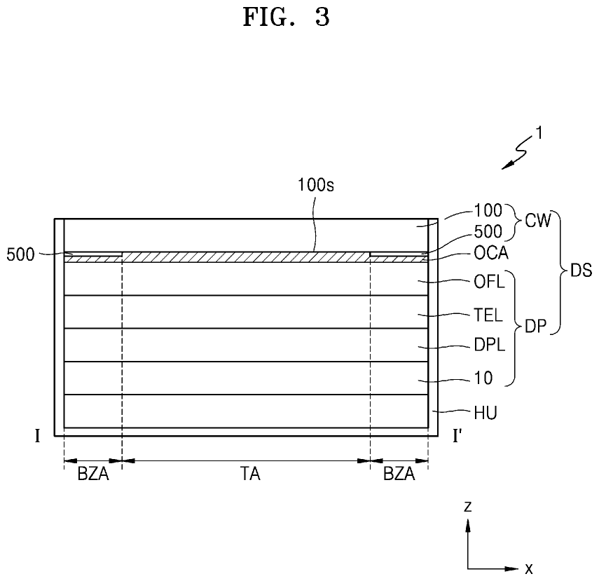

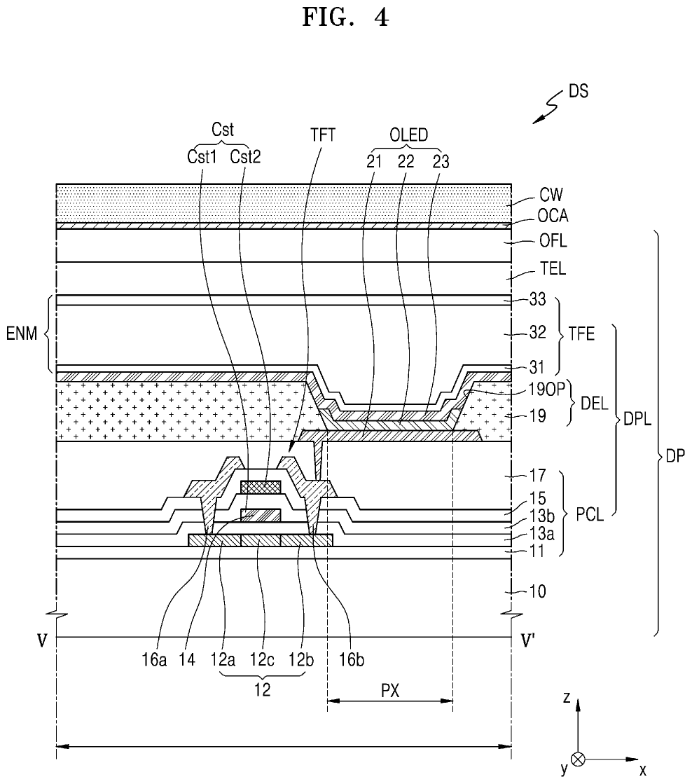

FIG. 3 is a cross-sectional view of the electronic device 1 taken along line I-I′ of FIG. 1, according to an embodiment of the present disclosure. FIG. 4 is a cross-sectional view of the display device DS that may be included in the electronic device 1, taken along line V-V′ of FIG. 1, according to an embodiment of the present disclosure.

Referring to FIGS. 3 and 4, the display device DS may include the display panel DP and the window CW disposed thereon. The display panel DP may have a stack structure of a substrate 10, and a display layer DPL, a touch electrode layer TEL, and an optical functional layer OFL on the substrate 10. The substrate 10 may also be referred to as a display substrate so as to make distinction from the window substrate and encapsulation substrate to be described. Referring to FIG. 4, the display layer DPL may include a pixel circuit layer PCL including a thin-film transistor TFT, a display element layer DEL including a display element, and an encapsulation member ENM, such as a thin-film encapsulation layer TFE or an encapsulation substrate. Insulating layers may be arranged between the substrate 10 and the display layer DPL, and in the display layer DPL. The display element may include a light-emitting diode, and for example, is illustrated as, in FIGS. 3 and 4, an organic light-emitting diode OLED of FIG. 4. Hereinafter, embodiments are described as if the electronic device 1 includes the organic light-emitting diode OLED as a display element, but the present disclosure is not limited thereto. According to an embodiment of the present disclosure, the display element may be a light-emitting diode including an inorganic material or a quantum dot light-emitting diode including a quantum dot and/or a quantum rod. For example, an emission layer of the display element may include an organic material, include an inorganic material, include a quantum dot, include an organic material and a quantum dot, or include an inorganic material and a quantum dot.

The substrate 10 may include glass or a polymer resin. Here, the polymer resin may include at least one of, for example, polyether sulfone, polyacrylate, polyether imide, polyethylene naphthalate, polyethylene terephthalate, polyphenylene sulfide, polyimide, polycarbonate, cellulose triacetate, or cellulose acetate propionate. The substrate 10 including a polymer resin may be flexible, and may be foldable, rollable, and/or bendable. The substrate 10 may have a multi-layer structure including a layer including the above-described polymer resin and an inorganic layer. In an embodiment of the present disclosure, the substrate 10 may have a structure of an organic layer/an inorganic layer/an organic layer.

The pixel circuit layer PCL may be disposed on the substrate 10. FIG. 4 illustrates that the pixel circuit layer PCL includes the thin-film transistor TFT, and a buffer layer 11, a first insulating layer 13a, a second insulating layer 13b, a third insulating layer 15, and a planarization layer 17, which are disposed below and/or on components of the thin-film transistor TFT.

The buffer layer 11 may be configured to reduce or block penetration of foreign materials, moisture, or ambient air from a bottom portion of the substrate 10 and may provide a flat surface on the substrate 10. The buffer layer 11 may include an inorganic insulating material, such as silicon nitride (SiNₓ), silicon oxynitride (SiON), or silicon oxide (SiOₓ), and may be a single layer or multilayer including the above inorganic insulating material. In an embodiment of the present disclosure, the buffer layer 11 may include an organic material, or an organic/inorganic complex, and may have a single layer or a multilayer structure of an inorganic material and an organic material.

The thin-film transistor TFT on the buffer layer 11 may include a semiconductor layer 12, and the semiconductor layer 12 may include polysilicon (p-Si). Alternatively, the semiconductor layer 12 may include amorphous silicon (a-Si), an oxide semiconductor, or an organic semiconductor. The semiconductor layer 12 may include a channel region 12c, and a drain region 12a and a source region 12b, which are arranged respectively on both sides of the channel region 12c. A gate electrode 14 may overlap the channel region 12c. The thin-film transistor TFT may be connected to the organic light-emitting diode OLED and may drive the organic light-emitting diode OLED.

The gate electrode 14 may include a low-resistance metal material. The gate electrode 14 may include a conductive material including, for example, molybdenum (Mo), aluminum (Al), copper (Cu), or titanium (Ti), and may be formed in a multilayer or single layer including the conductive material or materials.

The first insulating layer 13a may be located between the semiconductor layer 12 and the gate electrode 14. The first insulating layer 13a may include an inorganic insulating material, such as, for example, silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ).

The second insulating layer 13b may be provided to cover the gate electrode 14. The second insulating layer 13b may include an inorganic insulating material, such as, for example, SiOₓ, SiNₓ, SiON, Al₂O₃, TiO₂, Ta₂O₅, HfO₂, or ZnOₓ.

An upper electrode Cst2 of a storage capacitor Cst may be disposed on the second insulating layer 13b. The upper electrode Cst2 may at least partially overlap the gate electrode 14 disposed therebelow. The gate electrode 14 and the upper electrode Cst2, which overlap with the second insulating layer 13b therebetween, may form the storage capacitor Cst. In other words, the gate electrode 14 may operate as a lower electrode Cst1 of the storage capacitor Cst.

As such, the storage capacitor Cst and the thin-film transistor TFT may overlap. Alternatively, according to an embodiment of the present disclosure, the storage capacitor Cst may not overlap the thin-film transistor TFT. In other words, the lower electrode Cst1 of the storage capacitor Cst is a component separate from the gate electrode 14, and may be spaced apart from the gate electrode 14.

The upper electrode Cst2 may include, for example, aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multilayer including such a material or materials.

The third insulating layer 15 may cover the upper electrode Cst2. The third insulating layer 15 may include an inorganic insulating material, such as, for example, SiOₓ, SiNₓ, SiON, Al₂O₃, TiO₂, Ta₂O₅, HfO₂, or ZnOₓ. The third insulating layer 15 may be a single layer or multilayer including the inorganic insulating material described above.

A drain electrode 16a and a source electrode 16b may each be located on the third insulating layer 15. The drain electrode 16a and the source electrode 16b may be respectively connected to the drain region 12a and the source region 12b through contact holes formed in the insulating layers therebelow. The drain electrode 16a and the source electrode 16b may include a material having good conductivity. The drain electrode 16a and the source electrode 16b may include a conductive material including, for example, Mo, Al, Cu, or Ti, and may be formed in a multilayer or single layer including the conductive material or materials. According to an embodiment of the present disclosure, the drain electrode 16a and the source electrode 16b may have a multilayer structure, for example, a tri-layer structure, of Ti/Al/Ti.

The planarization layer 17 may be located to cover the drain electrode 16a and the source electrode 16b. The planarization layer 17 may have a flat top surface so that a bank layer 19 and a pixel electrode 21, which are to be described, located on the planarization layer 17 are flat.

The planarization layer 17 may include an organic insulating material or an inorganic insulating material, and may have a single or multi-layer structure. The planarization layer 17 may include an organic insulating material, such as a general-purpose polymer, for example, polymethylmethacrylate (PMMA) or polystyrene (PS), a polymer derivative having a phenol-based group, an acrylic-based polymer, an imide-based polymer, an arylether-based polymer, an amide-based polymer, a fluorine-based polymer, a p-xylene-based polymer, a vinyl alcohol-based polymer, or a blend thereof. When the planarization layer 17 is to be formed, a layer may be formed and then a chemical mechanical polishing (CMP) process may be performed on a top surface of the layer to provide a flat top surface. When the planarization layer 17 is formed through a spin coating process, a flat top surface may be obtained through the coating and baking process without performing a chemical mechanical polishing (CMP) process.

The display element layer DEL may be disposed on the pixel circuit layer PCL having the above-described structure. The display element layer DEL includes the organic light-emitting diode OLED as a display element, and the organic light-emitting diode OLED may have a stack structure of a pixel electrode 21, an emission layer 22, and a common electrode 23. The pixel electrode 21 of the organic light-emitting diode OLED may be electrically connected to the thin-film transistor TFT through a contact hole defined in the planarization layer 17.

The pixel electrode 21 may include a conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). According to an embodiment of the present disclosure, the pixel electrode 21 may include a reflective layer including, for example, Ag, Mg, Al, Pt, Pd, Au, Ni, Nd, Ir, Cr, or a compound thereof. Alternatively, according to an embodiment of the present disclosure, the pixel electrode 21 may further include a layer formed of ITO, IZO, ZnO, or In₂O₃, on/below the reflective layer. In this case, the pixel electrode 21 may have a stacked structure including, for example, ITO/Ag/ITO.

A bank layer 19 having an opening 190P exposing at least a portion of the pixel electrode 21 may be disposed on the pixel electrode 21. For example, the bank layer 19 may be located on the planarization layer 17 to cover an edge of the pixel electrode 21, and may have the opening 190P through which central portion of the pixel electrode 21 is exposed. The bank layer 19 may include an organic insulating material and/or an inorganic insulating material. For example, the bank layer 19 may be formed of an organic insulating material such as, for example, polyimide, polyamide, acrylic resin, benzocyclobutene, hexamethyldisiloxane (HMDSO), or phenolic resin by a spin coating process or the like. Alternatively, the bank layer 19 may include an inorganic insulating material such as, for example, silicon oxide (SiOₓ), silicon nitride (SiNₓ), or silicon oxynitride (SiON). The opening 190P may define an emission region of a light emitted from the organic light-emitting diode OLED. For example, a size/width of the opening 190P may correspond to a size/width of the emission region. Accordingly, a size and/or a width of the sub-pixel PX may be dependent on a size and/or a width of the opening 190P of the corresponding bank layer 19.

The emission layer 22 may be arranged at the opening 190P of the bank layer 19. The emission layer 22 may include a high-molecular weight organic material or low-molecular weight organic material, which emits a light of certain color, for example, red, green, blue, or white. Alternatively, the emission layer 22 may include an inorganic light-emitting material or a quantum dot. In an embodiment of the present disclosure, the emission layer 22 may include a fluorescent material or a phosphorescent material.

A first functional layer and a second functional layer may be disposed below and on the emission layer 22. The first functional layer may include, for example, a hole transport layer (HTL) or may include an HTL and a hole injection layer (HIL). The second functional layer may include an electron transport layer (ETL) and/or an electron injection layer (EIL). However, the present disclosure is not limited thereto. The first functional layer and the second functional layer may be selectively and respectively disposed on and below the emission layer 22. Thus, the emission layer 22 may generate a color light corresponding to the sub-pixel PX, and may be interposed between the hole transport layer (HTL) and the electron transport layer (ETL).

Like the common electrode 23 described below, the first functional layer and/or the second functional layer may be a common layer formed to entirely cover the substrate 10.

The common electrode 23 may be disposed on the pixel electrode 21 and may overlap the pixel electrode 21. The common electrode 23 may include a conductive material with a low work function. For example, the common electrode 23 may include a (semi-)transparent layer including, for example, Ag, Mg, Al, Pt, Pd, Au, Ni, Nd, Ir, Cr, lithium (Li), calcium (Ca), or an alloy thereof. Alternatively, the common electrode 23 may further include a layer including ITO, IZO, ZnO, or In₂O₃, on the (semi-)transparent layer including such a material. The common electrode 23 may be integrally formed to entirely cover the substrate 10. Layers from the pixel electrode 21 to the common electrode 23 formed in the display area DA may constitute the organic light-emitting diode OLED.

The encapsulation member ENM may be disposed on the display element layer DEL. According to an embodiment of the present disclosure, as shown in FIG. 4, the encapsulation member ENM may include the thin-film encapsulation layer TFE. However, the present disclosure is not limited thereto. According to an embodiment of the present disclosure, the encapsulation member ENM may include the encapsulation substrate. The encapsulation substrate may include, for example, glass. According to an embodiment of the present disclosure, the glass may be ultra-thin glass (UTG).

The thin-film encapsulation layer TFE may be disposed on the display element layer DEL and cover the display element layer DEL. The thin-film encapsulation layer TFE may cover the display element layer DEL to prevent the display element layer DEL from being damaged or degraded by external impurities. The thin-film encapsulation layer TFE may include at least one inorganic layer and at least one organic layer. According to an embodiment of the present disclosure, the thin-film encapsulation layer TFE may include a first inorganic layer 31, an organic layer 32, and a second inorganic layer 33, which are sequentially stacked in the stated order. The first inorganic layer 31 and the second inorganic layer 33 may include one or more inorganic materials from among, for example, aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), and silicon oxynitride (SiON). The organic layer 32 may include a polymer-based material. Examples of the polymer-based material may include, for example, an acrylic resin, an epoxy resin, polyimide, and/or polyethylene. According to an embodiment of the present disclosure, the organic layer 32 may include acrylate. The organic layer 32 may be formed by curing monomer or applying polymer. In the present embodiment, each of the first inorganic layer 31, the organic layer 32, and the second inorganic layer 33 is shown as a single layer, but the present disclosure is not limited thereto. For example, in an embodiment of the present disclosure, at least one of the first inorganic layer 31, the organic layer 32, or the second inorganic layer 33 may be provided in plurality or may be omitted.

The touch electrode layer TEL may be disposed on the encapsulation member ENM, for example, the thin-film encapsulation layer TFE. The touch electrode layer TEL may obtain coordinate information according to an external input, for example, a touch event. The touch electrode layer TEL may include a touch electrode and signal lines (trace lines) connected to the touch electrode. The touch electrode layer TEL may detect an external input via a mutual capacitance method and/or a self-capacitance method. Alternatively, the touch electrode layer TEL may sense an external input by using an electromagnetic induction method or a pressure sensing method.

The touch electrode layer TEL may be directly formed on the display element layer DEL or may be separately formed and combined to the display element layer DEL via an adhesive member, such as an optical clear adhesive OCA. The thin-film encapsulation layer TFE may be interposed between the touch electrode layer TEL and the display element layer DEL. According to an embodiment of the present disclosure, the touch electrode layer TEL may be formed directly on the thin-film encapsulation layer TFE or the encapsulation substrate, and in this case, no adhesive layer may be formed between the touch electrode layer TEL and the thin-film encapsulation layer TFE or the encapsulation substrate. FIGS. 3 and 4 illustrate that the touch electrode layer TEL is arranged between the display element layer DEL and the optical functional layer OFL, but as another example, the touch electrode layer TEL may be disposed on the optical functional layer OFL.

The optical functional layer OFL may reduce reflectance of a light (external light) incident from the outside towards the electronic device 1, and enhance color purity of a light emitted from the electronic device 1. According to an embodiment of the present disclosure, the optical functional layer OFL may include a retarder and/or a polarizer. The retarder may be a film type or liquid crystal coating type, and may include a A/2 retarder and/or a A/4 retarder. The polarizer may also be a film type or a liquid crystal coating type. The film type polarizer may include an elongated synthetic resin film, and the liquid crystal coating type polarizer may include liquid crystals arranged in a certain arrangement.

According to an embodiment of the present disclosure, the optical functional layer OFL may include a destructive interference structure. The destructive interference structure may include a first reflective layer and a second reflective layer arranged on different layers. A first reflective light and a second reflective light reflected respectively from the first reflective layer and the second reflective layer may be destructively interfered, and accordingly, reflectance of an external light may be reduced. According to an embodiment of the present disclosure, the optical functional layer OFL may include a filter plate including a black matrix and color filters. For example, the filter plate may include color filters, a black matrix, and an overcoat layer arranged in each sub-pixel PX. The arrangement of the color filters may be determined by taking into account emission colors of sub-pixels PX included in the display panel DP. Thus, the desired color may be realized by filtering the light emitted by each of the sub-pixels PX with the color filter.

An adhesive member may be arranged between the touch electrode layer TEL and the optical functional layer OFL. A general adhesive member known in the related art may be employed as the adhesive member without limitation. For example, the adhesive member may be the optical clear adhesive OCA.

The window CW may be disposed on the optical functional layer OFL. The window CW may be separately formed and the adhesive member may be arranged between the window CW and the optical functional layer OFL. For example, as shown in FIGS. 3 and 4, the adhesive member may be the optical clear adhesive OCA. However, the present disclosure is not limited thereto. According to an embodiment of the present disclosure, the window CW may be directly formed on the optical functional layer OFL.

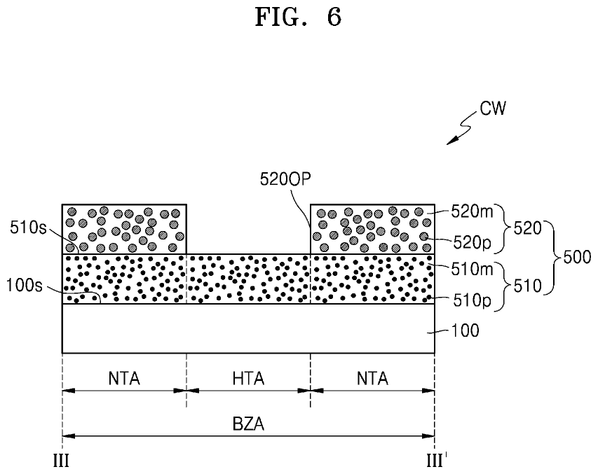

As shown in FIG. 3, the window CW may include a window substrate 100 and a printed layer 500 disposed on a rear surface 100s of the window substrate 100. The printed layer 500 may define the bezel area BZA. At least a portion of the printed layer 500, for example, a second printed layer 520 of FIG. 6, may overlap the optical clear adhesive OCA for adhering the window CW and the display panel DP, for example, the optical functional layer OFL of the display panel DP.

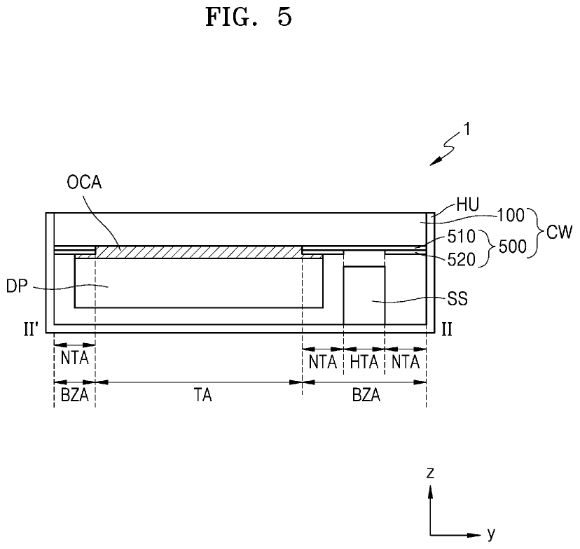

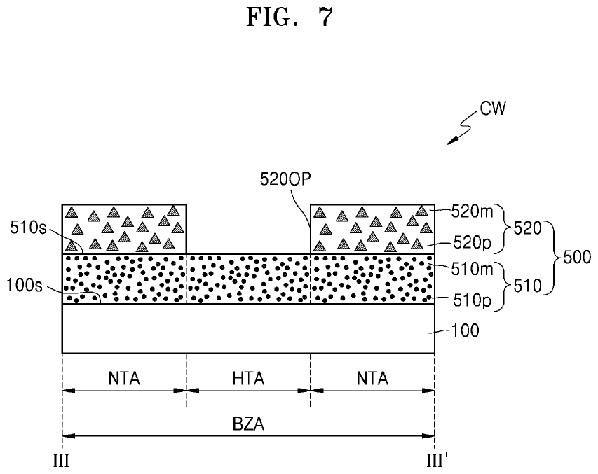

FIG. 5 is a cross-sectional view of the electronic device taken along line II-II′ of FIG. 1, according to an embodiment of the present disclosure. FIGS. 6 and 7 are each a cross-sectional view of a window that may be included in the electronic device, taken along line III-III′ of FIG. 2, according to an embodiment of the present disclosure.

Referring to FIGS. 5, 6, and 7, the window CW may include the window substrate 100 and the printed layer 500. For ease of illustration, the window CW in each of FIGS. 6 and 7 is inverted with respect to the window in FIG. 5.

The window substrate 100 may include a transparent insulating material.

According to an embodiment of the present disclosure, the window substrate 100 may include a glass material or a polymer resin. For example, the window substrate 100 may include a polymer resin, such as, for example, polyether sulfone, polyacrylate, polyether imide, polyethylene naphthalate, polyethylene terephthalate, polyphenylene sulfide, polyarylate, polyimide, polycarbonate, or cellulose acetate propionate. According to an embodiment of the present disclosure, the window substrate 100 may include ultra-thin glass (UTG) having enhanced intensity via a method such as chemical enhancement or thermal enhancement. In an embodiment of the present disclosure, the ultra-thin glass (UTG) for the window substrate 100 may have a thickness of about 2 mm or less. In an embodiment of the present disclosure, the ultra-thin glass (UTG) for the window substrate 100 may have a thickness of about 0.1 mm or less. According to an embodiment of the present disclosure, the window substrate 100 may have a structure in which a flexible polymer layer is arranged on a surface of a glass substrate, or may include only a polymer layer.

The printed layer 500 may include a first printed layer 510 disposed on the rear surface 100s of the window substrate 100 and the second printed layer 520 disposed on a rear surface 510s of the first printed layer 510. The second printed layer 520 may include an opening 520OP. The opening 520OP may overlap the first printed layer 510. The window substrate 100 may be divided into the transmission area TA and the bezel area BZA. The printed layer 500 may define the bezel area BZA. The printed layer 500 is not arranged in the transmission area TA. According to an embodiment of the present disclosure, as described above with reference to FIG. 1, when the bezel area BZA entirely surrounds the transmission area TA on a plane, the printed layer 500 may have a closed-loop shape having an opening corresponding to the transmission area TA on a plane. Accordingly, the bezel area BZA may define a shape of the transmission area TA.

The bezel area BZA may be an area having a relatively low light transmittance compared to the transmission area TA, and may include the printed layer 500 which contains an opaque material that blocks a light. The bezel area BZA may include the non-transmission area NTA and the semi-transmission area HTA. Among the bezel area BZA, a portion where the second printed layer 520 is arranged may be defined as the non-transmission area NTA, and a portion where the opening 520OP is arranged may be defined as the semi-transmission area HTA.

As shown in FIGS. 2 and 5-7, the sensor SS arranged in an internal space of the housing HU may overlap the opening 520OP of the second printed layer 520. In other words, the sensor SS may overlap the semi-transmission area HTA of the bezel area BZA. In an embodiment of the present disclosure, a portion of the sensor SS may overlap the non-transmission area NTA. According to an embodiment of the present disclosure, the sensor SS may be an RGB (Red, Green, Blue) sensor. According to an embodiment of the present disclosure, the sensor SS may be a proximity sensor and/or an illumination sensor. According to an embodiment of the present disclosure, the sensor SS may be a type in which a proximity sensor and an illumination sensor are integrated.

The first printed layer 510 may include a first pigment particle 510p, as shown in FIG. 6. In detail, the first printed layer 510 may include the first pigment particle 510p distributed in a resin-based first base material 510m. According to an embodiment of the present disclosure, the first pigment particle 510p may have a color that prevents the bezel area BZA from being well visible, and for example, may use a black pigment, such as carbon black. Carbon black may absorb all wavelengths A that are present in visible light (λ≈380-780 nm). The resin-based first base material 510m may include, for example, a modified acrylic resin.

The first pigment particle 510p of the first printed layer 510 may be distributed in the resin-based first base material 510m through a distribution process. According to an embodiment of the present disclosure, the distribution process may be performed, for example, via a three roll mill method, a beads mill method, and/or a drais mill method. While the distribution process is performed, the first pigment particle 510p may not only be distributed in the resin-based first base material 510m at a high degree, but also have a reduced particle size by being pulverized.

A distribution degree and particle size of the first pigment particle 510p are adjusted through the distribution process, thereby adjusting an optical characteristic of the first printed layer 510. For example, impression of a color, light-shielding power, and transmittance of the first printed layer 510 may vary. According to an embodiment of the present disclosure, the first printed layer 510 may have the optical characteristic required by the sensor SS, for example, a proximity sensor and/or an illumination sensor. For example, the first printed layer 510 may satisfy the transmittance requirement in a specific wavelength band suitable for the proximity sensor and/or the illumination sensor.

According to an embodiment of the present disclosure, a size (for example, a diameter) of the first pigment particle 510p may be about 0.5 μm to about 5 μm. When the first pigment particle 510p has a size outside the above range, a light transmittance of the first printed layer 510 may not satisfy an optical characteristic required by the sensor SS, for example, the proximity sensor and/or the illumination sensor. In an embodiment of the present disclosure, the first printed layer 510 may have relatively high transmittance for a light having a wavelength in the infrared range, and relatively low transmittance for a light having a wavelength in the visible light range.

According to an embodiment of the present disclosure, a light transmittance in an infrared area of the first printed layer 510 may be equal to or greater than about 80%. According to an embodiment of the present disclosure, the light transmittance of the first printed layer 510 at a wavelength of about 940 nm to about 1,000 nm may be equal to or greater than about 80%. According to an embodiment of the present disclosure, a light transmittance in a visible light area of the first printed layer 510 may be less than about 5%. According to an embodiment of the present disclosure, the visible light area may be a wavelength band of about 380 nm to about 780 nm. According to an embodiment of the present disclosure, a light transmittance of the first printed layer 510 at a wavelength of about 550 nm may be less than 5%.

The second printed layer 520 may include a second pigment particle 520p. According to an embodiment of the present disclosure, the second printed layer 520 may include the second pigment particle 520p distributed in a resin-based second base material 520m. FIGS. 6 and 7 illustrate the second printed layer 520 as if the second pigment particle 520p is entirely distributed in the resin-based second base material 520m, but the present disclosure is not limited thereto. According to an embodiment of the present disclosure, at least a portion of the second printed layer 520 may have a form in which the second pigment particle 520p is agglomerated without being distributed.

The second pigment particle 520p may have a color that prevents the bezel area BZA from being visible, and for example, may use a black pigment, such as carbon black. According to an embodiment of the present disclosure, as shown in FIG. 6, the second pigment particle 520p may include a material the same as that of the first pigment particle 510p. However, the present disclosure is not limited thereto. For example, the second pigment particle 520p may include a material different from that of the first pigment particle 510p, as shown in FIG. 7. The resin-based second base material 520m may include a modified acrylic resin. In FIGS. 6 and 7, the first base material 510m of the first printed layer 510 and the second base material 520m of the second printed layer 520 are a same material, but according to an embodiment of the present disclosure, base materials of the first printed layer 510 and the second printed layer 520 may include different materials. In an embodiment of the present disclosure, the first printed layer 510 and the second printed layer 520 may be formed of the same material, for example, the same material for the pigment particle such as carbon black and the same base material such as the same modified acrylic resin. However, the present disclosure is not limited thereto.

A size (for example, a diameter) of the second pigment particle 520p of the second printed layer 520 may be greater than a size (for example, a diameter) of the first pigment particle 510p of the first printed layer 510. For example, according to an embodiment of the present disclosure, the size (for example, the diameter) of the second pigment particle 520p may be about 8 μm to about 10 μm.

The second printed layer 520 may have a light transmittance in a visible light area lower than that of the first printed layer 510. For example, the light transmittance in the visible light area of the second printed layer 520 may be less than about 1%. Accordingly, the second printed layer 520 may define, in the bezel area BZA, the non-transmission area NTA through which a light is barely transmitted. On the other hand, the transmission area TA of the window CW may exhibit a light transmittance of about 90% or greater in the visible light area. In an embodiment of the present disclosure, each of the first printed layer 510 and the second printed layer 520 may have a thickness in a range from about 0.01 mm to about 1.0 mm, but the present disclosure is not limited thereto. For example, any suitable thickness capable of providing the required optical characteristics for each of the first printed layer 510 and the second printed layer 520 may be used.

The window CW may be disposed on the display panel DP, for example, on the optical functional layer OFL. The window CW may be separately formed, and an adhesive member may be arranged between the window CW and the display panel DP. A portion of the second printed layer 520, for example, a portion adjacent to the transmission area TA, may overlap the adhesive member, for example, the optical clear adhesive OCA, for combining the display panel DP and the window CW.

The opening 520OP of the second printed layer 520 may expose the first printed layer 510. The first printed layer 510 exposed by the opening 520OP of the second printed layer 520 may define the semi-transmission area HTA having an optical characteristic required by the sensor SS.

The opening 520OP of the second printed layer 520 may be at least partially filled by the air. For example, there may be no additional process to form an additional layer to fill the opening 520OP. thereby simplifying the manufacturing process of the electronic device 1 and reducing cost.

The first printed layer 510 and the second printed layer 520 may be sequentially formed. For example, the second printed layer 520 may be formed after the first printed layer 510 is formed on the rear surface 100s of the window substrate 100. The first printed layer 510 and the second printed layer 520 may be formed via a pad printing method in which ink is applied to a pad made of silicon (Si) or rubber and the pad is brought into contact with a surface of an object to be printed. However, the present disclosure is not limited thereto. According to an embodiment of the present disclosure, the first printed layer 510 and the second printed layer 520 may be formed via, for example, a silk screen method, a spray method, or the like.

According to a comparative example, a window includes a first printed layer disposed on a rear surface of a window substrate and having an opening, and a second printed layer disposed on a rear surface of the first printed layer and having an opening overlapping the opening of the first printed layer, and may include a third printed layer including a dye, as a separate printed layer for a sensor to fill the openings of the first printed layer and second printed layer. The opening of the first printed layer may correspond to a semi-transmission area overlapping the sensor. The dye included in the third printed layer is a material distinguished from a pigment, wherein the dye dissolves well in a host material, such as water and/or oil, whereas the pigment does not dissolve well relatively in water or oil. The dye relatively easily realizes an optical characteristic compared to the pigment, but has low reliability, for example, reacting with an adhesive member, such as an optical clear adhesive OCA, in a humid condition. Accordingly, a transparent layer for preventing a contact with the optical clear adhesive OCA may be further arranged to cover the third printed layer. Printed layers including different materials are formed via separate processes, and thus in the comparative example, the number of processes may be high, costs may be high, and a defect rate may be high due to insertion of a foreign material between the processes.

Meanwhile, according to an embodiment of the present disclosure, a third printed layer including a separate dye, and a transparent layer are not included, the first printed layer 510 is exposed at the opening 520OP of the second printed layer 520 corresponding to the semi-transmission area HTA, and the size and distribution degree of the first pigment particle 510p included in the first printed layer 510 are adjusted via the distribution process described above, thereby realizing the optical characteristic required by the sensor SS. Accordingly, in an embodiment of the present disclosure, the number of processes of the printed layer 500 is reduced and thus costs and a defect rate may be reduced.

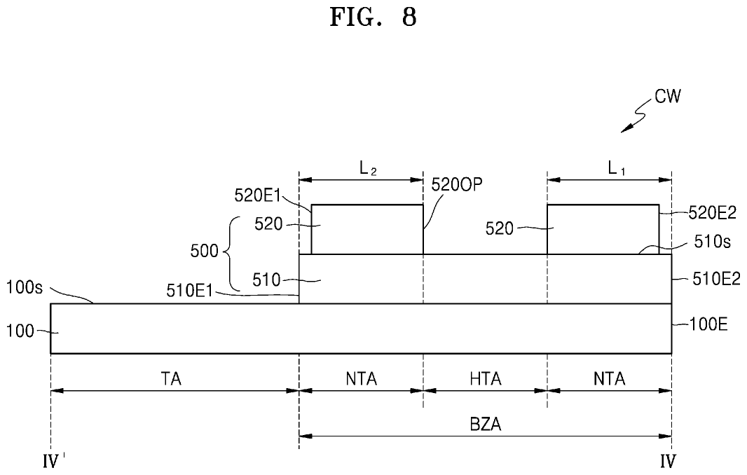

FIG. 8 is a cross-sectional view of the window CW taken along line IV-IV′ of FIG. 2.

Referring to FIG. 8, the printed layer 500 may have a stepped portion, and the second printed layer 520 may have a step difference from the first printed layer 510. According to an embodiment of the present disclosure, a (1-1)^{th} edge 510E1 of the first printed layer 510 may be formed to protrude towards the transmission area TA than a (2-1)^{th} edge 520E1 of the second printed layer 520. A location of the second printed layer 520 is aligned based on an edge of the first printed layer 510, and thus the second printed layer 520 does not intrude into the transmission area TA.

Similarly, a (1-2)^{th} edge 510E2 of the first printed layer 510 opposite to the transmission area TA may be formed to protrude over a (2-2)^{th} edge 520E2 of the second printed layer 520 opposite to the transmission area TA. A location of the second printed layer 520 is aligned based on an edge of the first printed layer 510, and thus the second printed layer 520 may not flow down to the outside of the window substrate 100.

According to an embodiment of the present disclosure, the (1-2)^{th} edge 510E2 of the first printed layer 510 may match an edge 100E of the window substrate 100. According to an embodiment of the present disclosure, the (1-1)^{th} edge 510E1 of the first printed layer 510 may be located at a border between the transmission area TA and the bezel area BZA of the window CW.

A first distance L1 from the edge 100E of the window substrate 100 to the opening 520OP of the second printed layer 520 may be equal to or greater than about 0.08 mm. According to an embodiment of the present disclosure, the first distance L1 may be about 0.08 mm to about 0.32 mm. According to an embodiment of the present disclosure, the first distance L1 may be about 0.08 mm.

A second distance L2 from the (1-1)^{th} edge 510E1 of the first printed layer 510 to the opening 520OP of the second printed layer 520 may be equal to or greater than about 0.15 mm. According to an embodiment of the present disclosure, the second distance L2 may be about 0.15 mm to about 0.5 mm. According to an embodiment of the present disclosure, the second distance L2 may be about 0.15 mm.

According to an embodiment of the present disclosure, by including a first printed layer arranged in a bezel area and a second printed layer having an opening, and controlling a size of a pigment particle distributed in the first printed layer, a window to which a sensor, for example, a proximity sensor and/or an illumination sensor, is applicable may be provided. Because a separate printed layer for a sensor is not included, processes are economical and a defect rate may be reduced. However, the scope of the present disclosure is not limited by such effects.

It should be understood that embodiments described herein should be considered in a descriptive sense only and not for purposes of limitation. Descriptions of features or aspects within each embodiment should typically be considered as available for other similar features or aspects in other embodiments. While specific embodiments have been described with reference to the drawings, it will be understood by those of ordinary skill in the art that various changes in form and details may be made therein without departing from the spirit and scope of the present disclosure as defined by the appended claims.

What is claimed is:

1. A display device comprising:
a display substrate;
a display element arranged in a display area of the display substrate, and including a first electrode, a second electrode, and an emission layer arranged between the first electrode and the second electrode;
an encapsulation member disposed on the display element; and
a window disposed on the encapsulation member,
wherein the window comprises:
a window substrate including a transmission area and a bezel area located outside the transmission area;
a first printed layer disposed on the window substrate in the bezel area, and including a first pigment particle distributed in a first base material; and
a second printed layer disposed on the first printed layer in the bezel area, and including an opening overlapping the first printed layer,
wherein a size of the first pigment particle is about 0.5 μm to about 5 μm in diameter.

2. The display device of claim 1, wherein the first pigment particle includes carbon black.

3. The display device of claim 1, wherein the second printed layer includes a second pigment particle.

4. The display device of claim 3, wherein the second pigment particle includes a material the same as that of the first pigment particle.

5. The display device of claim 3, wherein the second pigment particle includes carbon black.

6. The display device of claim 3, wherein a size of the second pigment particle is greater than the size of the first pigment particle.

7. The display device of claim 1, wherein the second printed layer has a step difference from the first printed layer.

8. The display device of claim 1, wherein the second printed layer has a light transmittance in a visible light area lower than that of the first printed layer.

9. The display device of claim 1, wherein a light transmittance of the first printed layer in an infrared area is equal to or greater than about 80%.

10. An electronic device comprising:
a display device including a display element arranged in a display area of a display substrate, and a window disposed on the display element; and
a housing accommodating the display device,
wherein the window comprises:
a window substrate including a transmission area and a bezel area outside the transmission area;
a first printed layer disposed on the window substrate in the bezel area, and including a first pigment particle distributed in a first base material; and
a second printed layer disposed on the first printed layer in the bezel area, and including an opening overlapping the first printed layer,
wherein a size of the first pigment particle is about 0.5 μm to about 5 μm in diameter.

11. The electronic device of claim 10, further comprising a sensor overlapping the opening of the second printed layer.

12. The electronic device of claim 11, wherein the sensor includes at least one of a proximity sensor and an illumination sensor.

13. The electronic device of claim 10, wherein the first pigment particle includes carbon black.

14. The electronic device of claim 10, wherein the second printed layer includes a second pigment particle.

15. The electronic device of claim 14, wherein the second pigment particle includes a material the same as that of the first pigment particle.

16. The electronic device of claim 14, wherein the second pigment particle includes carbon black.

17. The electronic device of claim 14, wherein a size of the second pigment particle is greater than the size of the first pigment particle.

18. The electronic device of claim 10, wherein the second printed layer has a step difference from the first printed layer.

19. The electronic device of claim 10, wherein the second printed layer has a light transmittance in a visible light area lower than that of the first printed layer.

20. The electronic device of claim 10, wherein a light transmittance of the first printed layer in an infrared area is equal to or greater than about 80%.
